(19) United States
(12) Patent Application Publication
(10) Pub. No.: US 2014/0043779 A1
(43) Pub. Date: Feb. 13, 2014

(54) METHOD OF MANUFACTURING ELECTRONIC DEVICE, ELECTRONIC DEVICE, ELECTRONIC APPARATUS, AND MOBILE OBJECT

(71) Applicant: Seiko Epson Corporation, Tokyo (JP)

(72) Inventor: Shinji Nakayama, Ina (JP)

(73) Assignee: Seiko Epson Corporation, Tokyo (JP)

(21) Appl. No.: 13/959,877

(22) Filed: Aug. 6, 2013

(30) Foreign Application Priority Data
Aug. 8, 2012 (JP) 2012-175752

(51) Int. Cl. H05K 3/30; H05K 7/02

(52) U.S. Cl. CPC H05K 3/30; H05K 7/02
USPC 361/752; 29/840

(57) ABSTRACT

A method of manufacturing an electronic device includes preparing a lid having a seal hole, a package having a seam ring (metalization portion) and constituting an internal space along with the lid, and a crystal vibrating piece (electronic component), mounting the crystal vibrating piece in the package, placing the lid on the package such that the seal hole and the seam ring overlap each other in plan view, seam-welding the outer circumferential portion of the lid and the package, and irradiating an energy beam to bond the seal hole and the seam ring and sealing the seal hole and the internal space.

### BACKGROUND

1. Technical Field

The present invention relates to a method of manufacturing an electronic device which depressurizes and seals the internal space of the electronic device, an electronic device manufactured by the method of manufacturing an electronic device, and an electronic apparatus and a mobile object in which the electronic device is mounted.

2. Related Art

In the related art, as a method of pressurizing and sealing the internal space of an electronic device, as disclosed in JP-A-2008-153485, a method including forming a package of the electronic device, mounting an electronic component inside the package, and welding a lid to the package is known. In the welding of the lid, a partial region at the edge of the lid is left, and in a portion other than the left region, seam welding of the lid and the package is performed. The package is heated in a vacuum atmosphere, degassing inside the package is performed from the partial region left without being seam-welded, a heating beam is irradiated onto the partial region, and the inside of the package is sealed in a depressurized state. According to this method, steps which have been heretofore performed, that is, forming a through hole in the package, the lid, or the like for degassing and closing the through hole with a solder material are not required, thereby achieving simplification of steps.

However, in the technique of the related art, when the positional relationship between the package and the lid or the seam ring is misaligned, or the like, the size (length) of the partial region left without being welded varies. In this case, in the partial region, if the size (length) to be sealed by the heating beam differs, an unsealed portion which is not sealed by the heating beam may be produced. In order to prevent the production of the unsealed portion, if the irradiation range of the heating beam increases in advance, the range in which the heating beam is irradiated again onto the seam-welded portion increases. At this time, outgas occurs, and the depressurized state inside the package is lowered. This is more conspicuous as the electronic device is reduced in size.

### SUMMARY

An advantage of some aspects of the invention is to solve at least a part of the problems described above, and the invention can be implemented as the following forms or application examples.

### Application Example 1

This application example is directed to a method of manufacturing an electronic device, the method including preparing a lid having a seal hole, a package having a metalization portion and constituting an internal space along with the lid, and an electronic component, mounting the electronic component in the package, placing the lid on the package such that the seal hole and the metalization portion overlap each other in plan view, welding the outer circumferential portion of the lid and the package, and irradiating an energy beam to bond the seal hole and the metalization portion and sealing the internal space.

According to the method of manufacturing an electronic device of this application example, the lid and the package are prepared in the preparing of the lid, the package, and the electronic component, the electronic component is mounted in the package in the mounting of the electronic component, and the lid and the package are arranged in the placing of the lid such that the seal hole and the metalization portion of the package overlap each other in plan view. In this case, the metalization portion corresponds to a metal film on the surface of the package, the seam ring provided between the lid and the package, or the like, and the term “plan view” refers to when viewed from a direction perpendicular to the lid placed on the package. In the welding of the outer circumferential portion of the lid and the package, the lid and the package are seam-welded and bonded together along the outer circumferential portion of the lid. At this time, since the seal hole is inside the outer circumferential portion of the lid, the internal space communicates with the outside of the lid and the package through the seal hole. In this state, for example, air in the internal space can be discharged from the seal hole to perform processing, such as depressurizing the internal space. Next, in the bonding of the seal hole and the metalization portion, in a state where the internal space is depressurized or the like, the seal hole and the metalization portion are bonded together by the energy beam, and the internal space is sealed. That is, the internal space in which the electronic component is accommodated is sealed from the outside while maintaining the depressurized state. According to this manufacturing method, in the placing of the lid, even when the positional relationship between the lid and the package is misaligned, or the like, the seal hole which corresponds to the partial region in the related art is not affected in the welding of the lid and the bonding of the seal hole and the metalization portion, and if the energy beam is irradiated, the internal space can be reliably sealed.

### Application Example 2

In the method of manufacturing an electronic device according to the application example, it is preferable that a metal solder is arranged on one surface of the lid, and in the bonding of the seal hole and the metalization portion, the one surface is arranged on a surface side of the lid placed on the metalization portion, and the seal hole and the metalization portion are bonded together by the metal solder.

According to this configuration, in the placing of the lid, the metal solder is arranged on the surface of the lid placed to face the metalization portion, and in the bonding of the seal hole and the metalization portion, the seal hole and the metalization portion are bonded together by the metal solder. With the use of the metal solder, a bonding temperature can be lowered compared to a case where the seal hole and the metalization portion are molten by seam-welding and bonded together. Accordingly, bonding of the seal hole and the metalization portion can be easily made, and damage or the like to the lid and the package including the metalization portion can be reduced.

### Application Example 3

In the method of manufacturing an electronic device according to the application example, it is preferable that the metal solder is a silver solder or a gold (Au)/tin (Sn) alloy solder.

According to this configuration, in the placing of the lid, the silver solder or the gold (Au)/tin (Sn) alloy solder is arranged on the surface of the lid placed to face the metalization portion, and in the bonding of the seal hole and the metalization portion, the seal hole and the metalization portion are bonded together by the silver solder or the gold (Au)/tin (Sn) alloy solder. With the use of the silver solder or the gold (Au)/tin (Sn) alloy solder, a bonding temperature can be lowered compared to a case where the seal hole and the metalization portion are molten by seam-welding and bonded together. Accordingly, bonding of the seal hole and the metalization portion can be easily made, and damage or the like to the lid and the package including the metalization portion can be reduced. In addition, in the gold (Au)/tin (Sn) alloy solder, improvement of corrosion resistance of the bonded portion is achieved.

### Application Example 4

In the method of manufacturing an electronic device according to the application example, it is preferable that, in the bonding of the seal hole and the metalization portion, a fillet-like portion is formed between the inner surface of the seal hole and the metalization portion.

According to this configuration, when the seal hole and the package are molten and directly bonded together, when the seal hole and the package are bonded together through a solder material, or the like, it is preferable that the fillet-like portion is formed so as to cover the bonded portion from the inner surface of the seal hole to the metalization portion. Accordingly, strength of the bonded portion can be improved and reliable sealing can be made. When a solder material is used, the molten solder material covers a portion between the lid and the metalization portion to form the fillet-like portion, melting of the lid and the metalization portion is avoided as much as possible, thereby achieving reduction of damage or the like.

### Application Example 5

In the method of manufacturing an electronic device according to the application example, it is preferable that the metalization portion of the package to be prepared in the preparing of the lid, the package, and the electronic component has a width in plan view at a position where the seal hole is arranged greater than a width in plan view at a different position.

According to this configuration, unlike the metalization portion of the related art, the metalization portion of the package does not have a substantially uniform width (width in plan view) in plan view, and the width in plan view of the metalization portion in which the seal hole is to be located is greater than other portions. For this reason, even if the positional relationship between the lid and the package is misaligned, the seal hole is not misaligned from the metalization portion, and the internal space can be reliably sealed.

### Application Example 6

In the method of manufacturing an electronic device according to the application example, it is preferable that the seal hole is formed by punching by a press, and in the placing of the lid, a surface of the lid on which punching starts is placed on the package.

According to this configuration, the seal hole formed by punching by press is sagged toward the inner surface thereof on the surface side on which punching by a press starts, and minute variation occurs toward the outer surface of the seal hole on an opposite side to the side on which punching starts. Accordingly, if the surface on the side on which punching starts is placed on the package, a gap or the like does not occur between the lid and the package by the effect of variation or the like, and reliable sealing is performed in the welding of the lid and the bonding of the seal hole and the metalization portion.

### Application Example 7

This application example is directed to an electronic device including a lid having a hole portion, a package, and an electronic component which is in an internal space formed by bonding the lid and the package, in which the hole portion is arranged at a position overlapping a bonded portion of the lid and the package in plan view.

According to the electronic device of this application example, the lid and the package are bonded together such that the hole portion of the lid and the bonded portion of the package overlap each other. In the electronic device having the above configuration, the hole portion is easily bonded directly to the bonded portion of the package, thereby sealing the internal space. Since the sealed hole portion is left in the completed electronic device, the hole portion also has a function as a marking for discriminating the mounting direction of the electronic device.

### Application Example 8

This application example is directed to an electronic apparatus in which the electronic device of Application Example 7 is mounted.

According to this application example, a reliable electronic apparatus can be obtained.

### Application Example 9

This application example is directed to a mobile object in which the electronic device of Application Example 7 is mounted.

According to this application example, a reliable mobile object can be obtained.

### BRIEF DESCRIPTION OF THE DRAWINGS

The invention will be described with reference to the accompanying drawings, wherein like numbers reference like elements.

FIG. 1A is a plan view showing the appearance of an electronic device according to Embodiment 1 of the invention, and FIG. 1B is a plan view showing the inside of the electronic device in a state where a lid is removed.

FIG. 2 is a sectional view showing the inside of the electronic device.

FIG. 3A is a sectional view showing a processing example of a seal hole of a lid, and FIG. 3B is a sectional view showing the bonded configuration of a package, a lid, and a seal hole.

FIG. 4 is a flowchart showing a method of manufacturing an electronic device.

FIG. 5 is a sectional view showing the bonded configuration of a package, a lid, and a seal hole of an electronic device according to Embodiment 2.

FIG. 6A is a plan view showing the configuration of an electronic device according to Embodiment 3, and FIG. 6B is a sectional view showing the bonded configuration of a package, a lid, and a seal hole.

FIG. 7A is a perspective view showing a personal computer in which an electronic device is mounted, FIG. 7B is a perspective view showing a mobile phone in which an electronic device is mounted, and FIG. 7C is a perspective view showing a mobile object in which an electronic device is mounted.

### DESCRIPTION OF EXEMPLARY EMBODIMENTS

Hereinafter, preferred examples of a method of manufacturing an electronic device of the invention, an electronic device, an electronic apparatus, and a mobile object will be described referring to the accompanying drawings.

### Embodiment 1

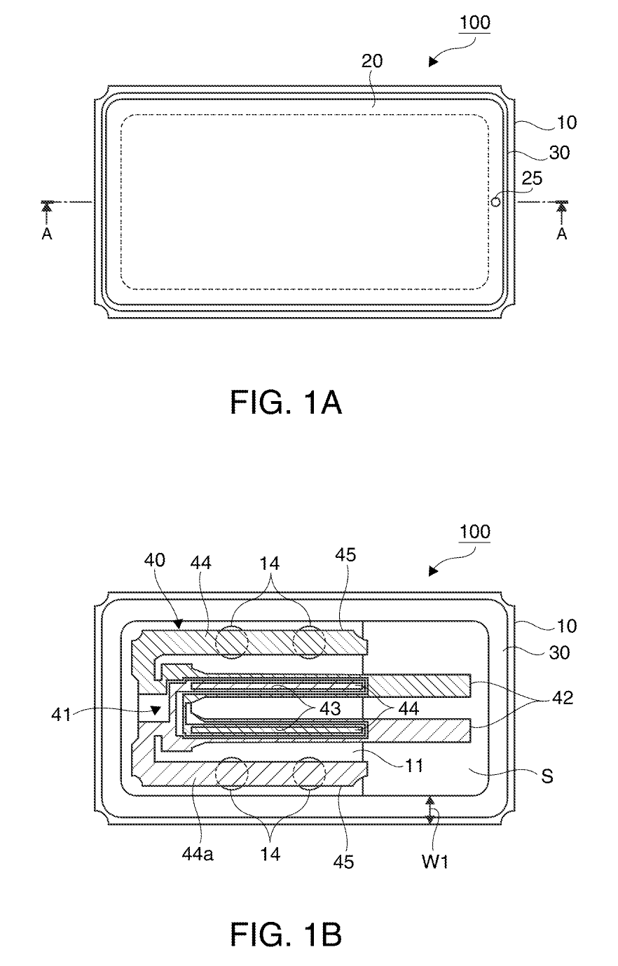

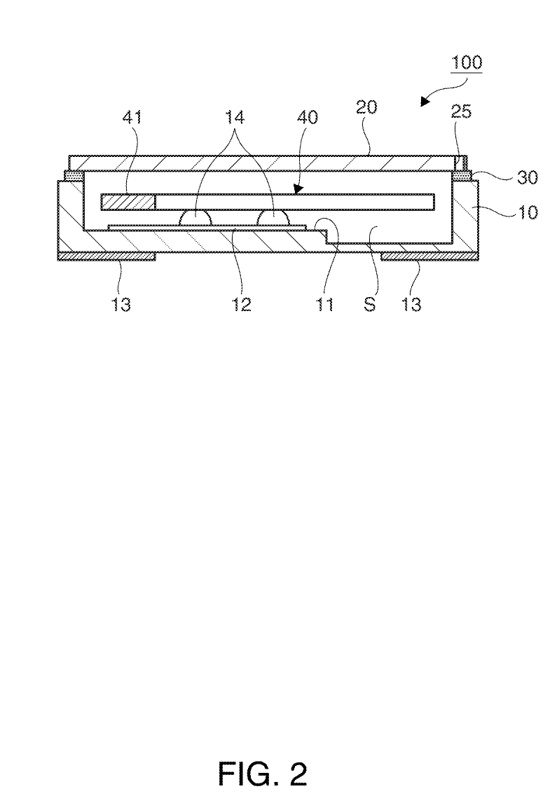

FIG. 1A is a plan view showing the appearance of an electronic device according to Embodiment 1 of the invention, and FIG. 1B is a plan view showing the inside of the electronic device in a state where a lid is removed. FIG. 2 is a sectional view showing the inside of the electronic device, and shows a section taken along the line A-A of the electronic device of FIG. 1A. As shown in the plan view of FIG. 1A, an electronic device 100 has a rectangular appearance in plan view, and includes a package 10, a lid 20, and a seam ring 30 which bonds the lid 20 to the package 10. In this case, the seam ring 30 is a metalization portion of the package 10, and the lid 20 has a seal hole (hole portion) 25 which is provided so as to overlap the seam ring 30 as a metalization portion in plan view. In this case, the seal hole 25 is provided at one place, and a circular through hole.

The package 10 of the electronic device 100 shown in FIG. 1B or 2 is molded using a ceramic green sheet made of aluminum oxide as an insulating material, and is formed by sintering after molding. The package 10 has an internal space S which is formed inside the package 10 and the side facing the lid 20 is opened, a step portion 11 which is provided in the internal space S, an electrode portion 12 which is provided in the step portion 11, and a mounting terminal 13 which is provided on the outer surface side and electrically connected to the electrode portion 12. In the internal space S, a crystal vibrating piece 40 as an electronic component which is fixed to the electrode portion 12 through a conductive adhesive 14 is accommodated. In this case, the conductive adhesive 14 contains microscopic particles of silver (Ag) in epoxy-based synthetic resin as an adhesive component exhibiting adhesion, and the electrode portion 12 and the mounting terminal 13 are formed by gold (Au) plating.

It is preferable that the lid 20 is made of a material which has a coefficient of thermal expansion close to the package 10 and is easy to bond. For example, the same ceramic material as the package 10, Kovar which is an alloy of iron (Fe) and cobalt (Co), or a metal, such as stainless steel, may be used, and in the electronic device 100, Kovar is used. The surface of Kovar is subjected to nickel (Ni) plating (not shown). The seam ring 30 is bonded to the package 10 in advance and makes it easy to bond the lid 20 to the package 10, and in the electronic device 100, Kovar is used. The seam ring 30 and the package surface on which the seam ring 30 is bonded have a uniform width in plan view. The width in plan view of the package surface is W1, and the width in plan view of the seam ring 30 is smaller than the width W1 in plan view of the package surface.

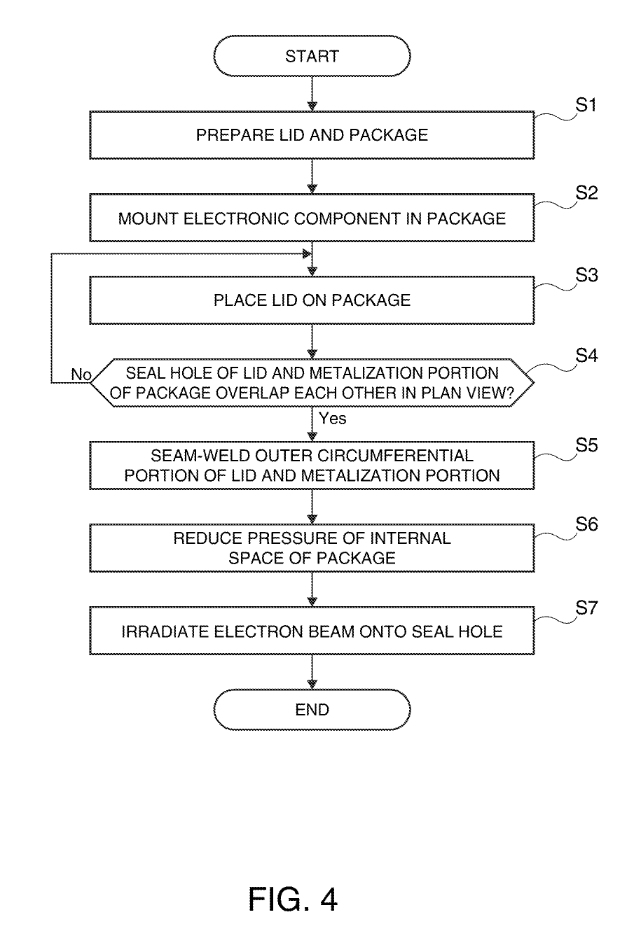

In the electronic device 100 having the above configuration, after the lid 20 is bonded to the seam ring 30 of the package 10, air in the internal space S is deflated from the seal hole 25, and the seal hole 25 is bonded to the seam ring 30 and sealed. Thus, the internal space S is reliably sealed in a depressurized state. A manufacturing method for bonding will be described below referring to a flowchart of FIG. 4.

In regard to the conductive adhesive 14, synthetic resin is not limited to epoxy, and silicone-based or polyimde-based conductive adhesive may be used, and the microscopic particles may be metal other than silver (Ag) or may be metal bump. The electrode portion 12 and the mounting terminal 13 may be nickel (Ni) plating or the like.

Next, the crystal vibrating piece 40 as an electronic component which is accommodated in the internal space S of the package 10 will be described. The crystal vibrating piece 40 as an example of an electronic component includes a base portion 41, a pair of vibrating arms 42 which extend in parallel from the base portion 41, long grooves 43 which are formed in the surfaces of a pair of vibrating arms 42 facing the lid 20 and the opposite surfaces to the surfaces, and are formed in the extension direction of the vibrating arms 42, and a pair of support arms 45 which extend from the base portion 41 in a direction perpendicular to the extension direction of the vibrating arms 42 in plan view and are bent in a direction parallel to the vibrating arms 42. The crystal vibrating piece 40 includes excitation electrodes 44 which are formed in a pair on a surface with no long grooves 43 formed inside the long grooves 43 and the vibrating arms 42, and lead electrodes 44a which are led from the excitation electrodes 44 to the support arms 45.

In the crystal vibrating piece 40, the base portion 41, the tuning fork vibrating arms 42, the long grooves 43 provided in the vibrating arms 42 can be formed with precision, for example, by wet-etching a material, such as a crystal wafer, using a hydrofluoric acid solution or the like. The excitation electrodes 44 and the lead electrodes 44a are formed by forming chromium (Cr) having high adhesion to crystal as an underlayer through vapor deposition or sputtering, forming an electrode film using gold (Au) which has low electrical resistance and is not easily oxidized, and patterning using photolithography.

When the electronic device 100 having the above configuration is mounted on a mounting substrate or the like, a driving voltage from the outside is transmitted from the mounting terminal 13 to the lead electrodes 44a of the support arms 45 of the crystal vibrating piece 40 through the electrode portion 12 and then transmitted to the excitation electrodes 44, whereby the vibrating arms 42 are bent in different directions and vibrate. In this case, since the crystal vibrating piece 40 has small rigidity due to the long grooves 43 provided in the vibrating arms 42 and easily vibrate, the vibrating arms 42 efficiently vibrate, thereby having satisfactory vibration characteristics. The crystal vibrating piece 40 is a so-called tuning fork vibrating piece.

An electronic component in the electronic device 100 is not limited to the crystal vibrating piece 40, and may be various forms other than a tuning fork vibrating piece, and the material may be piezoelectric materials, such as lithium tantalate (LiTaO₃), lithium tetraborate (Li₂B₄O₇), lithium niobate (LiNbO₃), lead zirconate titanate (PZT), zinc oxide (ZnO), and aluminum nitride (AlN), other than crystal, or non-piezoelectric materials, such as silicon or germanium, having a configuration in which a piezoelectric material is wound.

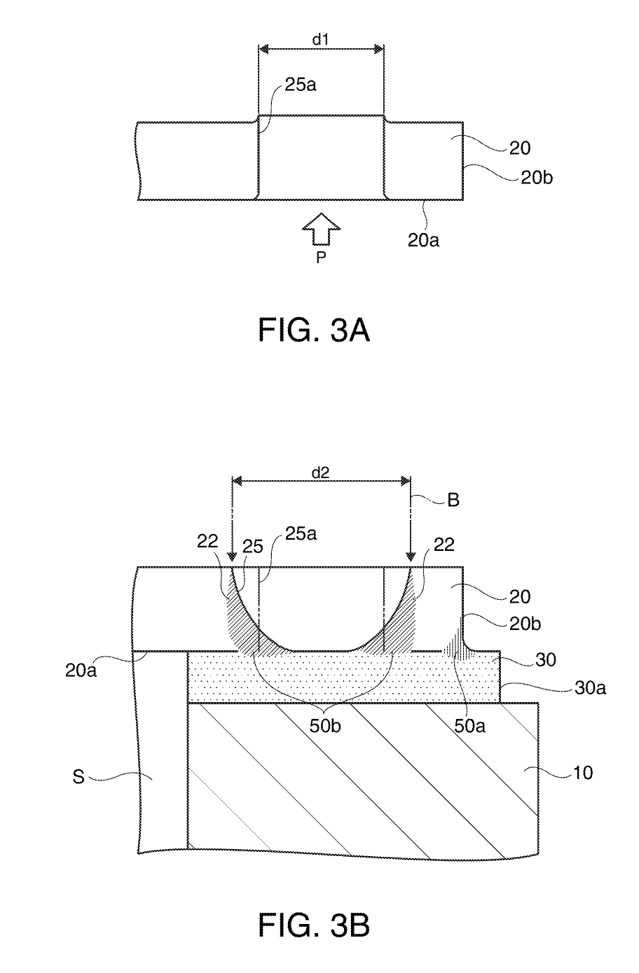

Next, a configuration which seals the internal space S of the package 10 in the electronic device 100 will be described. FIG. 3A is a sectional view showing a processing example of a seal hole of a lid, and FIG. 3B is a sectional view showing the bonded configuration of a package, a lid, and a seal hole. In the description, a seal hole is distinguished between a seal hole 25a in the single piece of the lid 20 and a seal hole 25 after sealing (FIGS. 1A and 1B and 2). Although the seal hole 25a can be formed in the lid 20 by punching by press or drilling, as shown in FIG. 3A, the seal hole 25a is formed in a circular shape having a hole diameter d1 by punching by press. Accordingly, the seal hole 25a has a shape in which the side of a lid surface 20a as the surface on the punching start side in a direction P of punching by press is pushed in a hole inner surface direction and sagged. On the surface opposite to the lid surface 20a, variation in a direction outside the hole occurs. Although the variation can be easily eliminated by barrel processing, in the bonding of the package 10 and the lid 20, it is preferable to place the lid surface 20a on the package 10 side, that is, on the seam ring 30. Accordingly, the lid 20 is placed without causing a gap or the like, which interferes with bonding or the like, with respect to the seam ring 30. The seal hole 25a is not limited to a circular through hole, and may be an elliptical shape, a rectangular shape, a polygonal shape, or the like. The seal hole 25a may be provided at multiple places, instead of one place.

If the lid 20 is placed on the seam ring 30 and bonded by seam-welding and energy beam irradiation, the bonded state shown in FIG. 3B is made. An outer circumferential portion 20b of the lid 20 has a similar shape smaller than an outer circumferential portion 30a of the seam ring 30. In bonding of the seam ring 30 and the lid 20, first, the outer circumferential portion 20b of the lid 20 and the seam ring 30 are seam-welded, and molten including nickel (Ni) plating on the surface of the lid 20 and bonded together, and a first bonded portion 50a is formed in the boundary of the outer circumferential portion 20b and the seam ring 30. An energy beam B having an irradiation diameter d2 greater than the hole diameter d1 is irradiated onto the seal hole 25a, the inner surface of the seal hole 25a is molten and bonded to the molten seam ring 30, and a second bonded portion 50b is formed in the boundary of the seal hole 25a and the seam ring 30. The seal hole 25 after bonding has a diameter greater than the seal hole 25a before bonding, that is, a diameter close to the irradiation diameter d2. The molten portions of the seal hole 25 of the lid 20 and the seam ring 30 spread toward the hole inner surface of the seal hole 25 to form a fillet-like portion 22 which has a substantially triangular sectional shape. The fillet-like portion 22 is formed, whereby the seal hole 25 and the seam ring 30 are bonded together to form the second bonded portion 50b for sealing the internal space S solidly. With the first bonded portion 50a and the second bonded portion 50b, the internal space S is blocked from the outside of the package 10 and the lid 20 and reliably sealed. The energy beam B described herein includes an electron beam, a laser, and the like.

Hereinafter, a method of manufacturing the electronic device 100 having the above bonded configuration will be described. FIG. 4 is a flowchart showing a method of manufacturing an electronic device. First, in Step S1, a lid and a package are prepared. Here, the lid 20 having the seal hole 25a formed by press processing and the package 10 having the electrode portion 12, the mounting terminal 13, the seam ring 30, and the crystal vibrating piece 40 are manufactured separately and prepared. That is, Step S1 corresponds to a preparation step. After preparation, the process progresses to Step S2.

In Step S2, an electronic component is mounted in the package. That is, the crystal vibrating piece 40 as an electronic component is fixed in a vibratable state and mounted in the internal space S of the package 10. Step S2 corresponds to a mounting step. After mounting, the process progresses to Step S3.

In Step S3, the lid is placed on the package. Specifically, the lid surface 20a of the lid 20 is placed on the seam ring 30 of the package 10. At this time, as described above, the outer circumferential portion 20b of the lid 20 is set to be smaller than the outer circumferential portion 30a of the seam ring 30, both outer circumferential portions are arranged such that the width therebetween is substantially uniform over the entire circumference, and the lid 20 and the seam ring 30 are arranged substantially in an adhesive state. After arrangement, the process progresses to Step S4.

In Step S4, it is determined whether or not the seal hole of the lid overlaps the metalization portion of the package in plan view. In this case, the metalization portion indicates the seam ring 30. The determination is made by image recognition using a robot or a worker who performs the placing operation in Step S3. If the package 10 and the lid 20 are arranged so as to overlap each other in plan view, the seal hole 25a of the lid 20 is arranged to be bondable to the seam ring 30. This arrangement is a key point, and the arrangement state is confirmed and determined in Step S4. Step S4 corresponds to a placement step along with Step S3. As the confirmation result, if the seal hole 25a and the seam ring 30 overlap each other, the process progresses to Step S5, and if the seal hole 25a and the seam ring 30 do not overlap each other, the process returns to Step S3.

If the seal hole 25a and the seam ring 30 overlap each other, in Step S5, the outer circumferential portion of the lid and the metalization portion are seam-welded. In this case, as shown in FIG. 3B, the outer circumferential portion 20b of the lid 20 and the seam ring 30 as a metalization portion are molten to form the first bonded portion 50a, and the entire circumference of the outer circumferential portion 20b of the lid 20 is bonded. Accordingly, the internal space S communicates with the outside only through the seal hole 25a and between the lid surface 20a of the lid 20 and the seam ring 30. In this case, the melting point of Kovar forming the lid 20 and the seam ring 30 is at high temperature of about 1450° C., and it is preferable that the boundary of the lid 20 and the seam ring 30 is seam-welded locally and rapidly. Step S5 corresponds to a first bonding step. After welding, the process progresses to Step S6.

In Step S6, the internal space of the package is depressurized. The package 10 and the lid 20 bonded by the first bonded portion 50a is placed in a pressurized atmosphere close to vacuum, and the internal space S is depressurized. That is, in the depressurized atmosphere, air in the internal space S is discharged to the outside in a depressurized state only through the seal hole 25a. Accordingly, the internal space S is in the same depressurized atmosphere as the outside. The internal space S may be closed and sealed in an inert gas atmosphere as well as the depressurized atmosphere. In this case, the internal space S in the depressurized atmosphere and the inert gas atmosphere is depressurized and sealed, and in Step S6, the internal space S is depressurized. After depressurization, the process progresses to S7.

In Step S7, an energy beam is irradiated onto the seal hole. Specifically, as shown in FIG. 3B, the energy beam B is irradiated onto the seal hole 25a to melt the inner surface of the seal hole 25a and the seam ring 30. The seal hole 25 and the seam ring 30 are reliably sealed by the fillet-like portion 22 in the seal hole 25 formed through melting and the second bonded portion 50b in the boundary of the seam ring 30. Accordingly, the internal space S in which the crystal vibrating piece 40 is accommodated is sealed completely from the outside. The crystal vibrating piece 40 can stably vibrate under a given depressurized atmosphere in the internal space S, and can thus contribute to stabilization of a timing device function of the electronic device 100. Step S7 corresponds to a second bonding step. With the above, the flow relating to the method of manufacturing an electronic device ends, and the electronic device 100 is completed. Since the sealed seal hole 25 is left in the completed electronic device 100, the seal hole 25 has an effect as a marking for discriminating a mounting direction of electronic device or the like.

### Embodiment 2

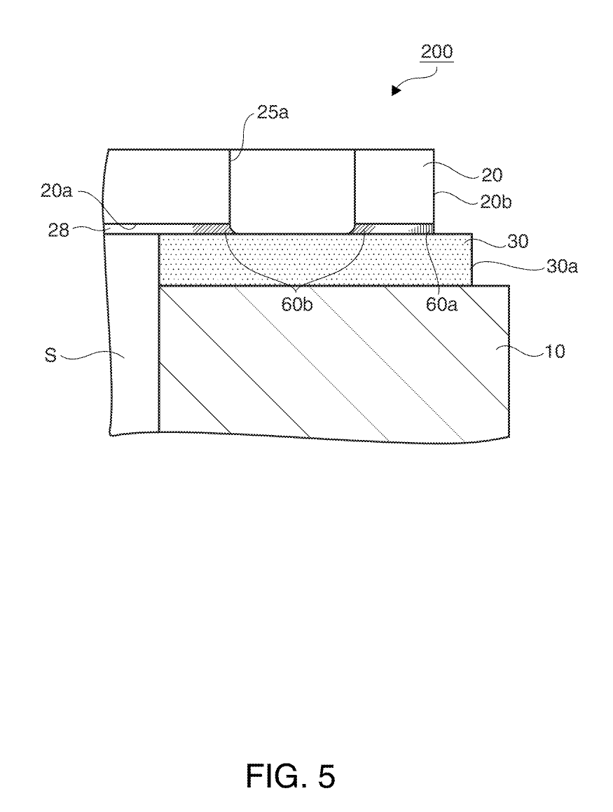

Next, another preferred example of an electronic device manufactured by a method of manufacturing an electronic device will be described. FIG. 5 is a sectional view showing the bonded configuration of a package, a lid, and a seal hole of an electronic device according to Embodiment 2. An electronic device 200 has the same configuration as the electronic device 100, except that only the bonded configuration of the package 10, the lid 20, and the seal hole 25a is different from the electronic device 100 of Embodiment 1. In the electronic device 200, the seam ring 30 is bonded to the package 10, and a silver (Ag) solder 28 is arranged on the entire lid surface 20a of the lid 20 as the surface side placed to face the seam ring 30.

The lid 20 is placed on the seam ring 30, and if bonding is made by seam-welding and energy beam irradiation, the bonded state shown in FIG. 5 is made. The outer circumferential portion 20b of the lid 20 has a similar shape smaller than the outer circumferential portion 30a of the seam ring 30. In bonding of the seam ring 30 and the lid 20, first, the lid surface 20a on the outer circumferential portion 20b side of the lid 20 and the seam ring 30 are seam-welded and the silver (Ag) solder 28 is molten, whereby the lid 20 and the seam ring 30 are bonded together through nickel (Ni) plating. In this case, the molten portion of the silver (Ag) solder 28 is a first bonded portion 60a. The energy beam B (see FIG. 3B) is irradiated onto the seal hole 25a, whereby the silver (Ag) solder 28 near the seal hole 25a is molten, and the lid 20 and the seam ring 30 are bonded together through nickel (Ni) plating. In this case, the molten potion of the silver (Ag) solder 28 is a second bonded portion 60b.

In this way, the lid 20 and the seam ring 30 are bonded together using the silver (Aa) solder 28, whereby bonding can be performed at a temperature lower than bonding in Embodiment 1, that is, at about 700° C. as the melting point of the silver (Ag) solder 28, the internal space S is blocked from the outside of the package 10 and the lid 20, and reliably sealed. Accordingly, in the electronic device 200, since processing can be performed at lower temperature, bonding can be easily performed, and thermal effect on the package 10, the lid 20, the crystal vibrating piece 40, or the like can be suppressed.

In bonding of the lid 20 and the seam ring 30, instead of the silver (Ag) solder 28, for example, a gold (Au)/tin (Sn) alloy solder or the like may be used. The melting point of the gold (Au)/tin (Sn) alloy solder is about 300° C. lower than the silver (Ag) solder 28, thereby lowering a bonding temperature. Accordingly, bonding of the lid 20 including the seal hole 25a and seam ring 30 is more easily performed, thermal effect on the package 10, the lid 20, the crystal vibrating piece 40, or the like is further suppressed, and improvement in corrosion resistance of the bonded portion is achieved compared to the silver (Ag) solder 28 or the like.

### Embodiment 3

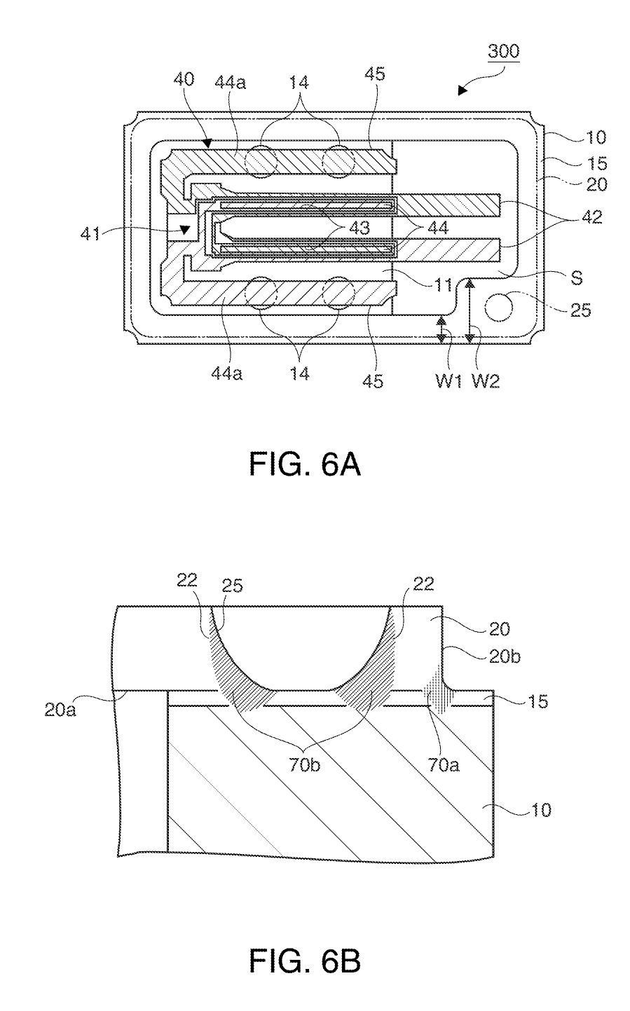

Next, another preferred example of an electronic device manufactured by a method of manufacturing an electronic device will be described. FIG. 6A is a plan view showing the configuration of an electronic device according to Embodiment 3, and FIG. 6B is a sectional view showing the bonded configuration of a package, a lid, and a seal hole. FIG. 6A shows a crystal vibrating piece 40 which is accommodated in the internal space S in a state where the lid 20 is removed. An electronic device 300 has the same configuration as the electronic device 100 or 200, except that the shape in plan view of the internal space S and the bonded configuration of the package 10, the lid 20, and the seal hole 25 are different from the electronic device 100 of Embodiment 1 or the electronic device 200 of Embodiment 2.

As shown in FIG. 6A, in the electronic device 300, the internal space S of the package 10 is narrowed inwardly at one corner of a rectangular shape. That is, the surface of the package 10 on which the lid 20 is placed has a width W1 in plan view and has a width W2 in plan view at one corner at which the seal hole 25 is arranged, and the width W2 in plan view is greater than the width W1 in plan view. A position at which the width W2 in plan view is formed may be a position other than the corner if there is no interference with vibration of the crystal vibrating piece 40.

As shown in FIG. 6B, a metal film 15 as a metalization portion is formed on the surface of the package 10 on which the lid 20 is placed. In this case, the metal film 15 is formed of nickel (Ni) by vapor deposition. Accordingly, even if the lid 20 placed on the package 10 is misaligned, the seal hole 25 is arranged so as to overlap the metal film 15 having the width W2 in plan view as a wide metalization portion in plan view. That is, a wide allowable range of misalignment when placing the lid 20 on the package 10 can be set.

If the metal film 15 and the lid 20 are bonded together by seam welding and energy beam irradiation, the bonded state shown in FIG. 6B is made. In bonding of the package 10 and the lid 20, first, the outer circumferential portion 20 side of the lid 20 and the metal film 15 of the package 10 are seam-welded, and molten and bonded together, and a first bonded portion 70a is formed by the outer circumferential portion 20b and the metal film 15. The energy beam B (see FIG. 3B) is irradiated, whereby the fillet-like portion 22 is formed in the seal hole 25, and the fillet-like portion 22 and the metal film 15 are bonded together to form a second bonded portion 70b. The internal space S is blocked from the outside of the package 10 and the lid 20 by the first bonded portion 70a and the second bonded portion 70b and can be reliably maintained in a sealed state. Since the width W2 in plan view of the package 10 at the position of the seal hole 25 is set to be large, heat is easily absorbed in seam welding and energy beam irradiation, and thermal effect on the package 10, the lid 20, the crystal vibrating piece 40, and the like is further suppressed.

In the electronic device 300, although the package 10 and the lid 20 are bonded together with the metal film 15 as a metalization portion, the package 10 and the lid 20 may be bonded together by a method using the seam ring 30 shown in FIG. 3B or a method of using the silver (Ag) solder 28 shown in FIG. 5 or the like. Although the width W2 in plan view spreads toward the inside of the internal space S, the width W2 in plan view may spread outward or may spread inward and outward.

### Electronic Apparatus

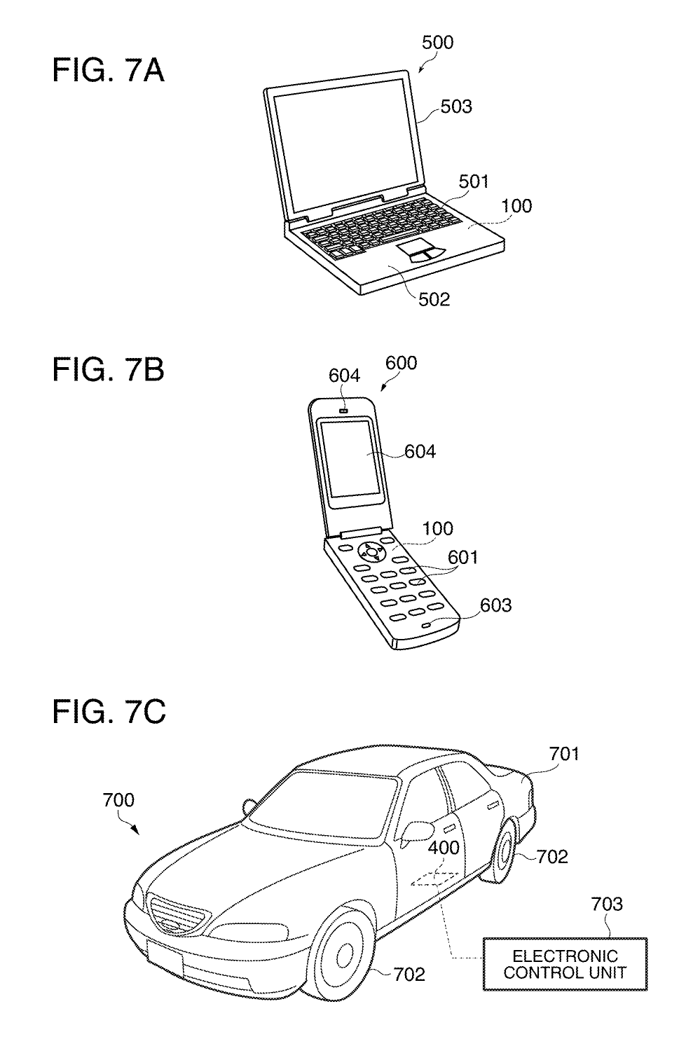

Next, an electronic apparatus and a mobile object in which the electronic device 100, 200, or 300, or an electronic device 400 is mounted will be described. FIG. 7A is a perspective view showing a personal computer in which an electronic device is mounted, FIG. 7B is a perspective view showing a mobile phone in which an electronic device is mounted, and FIG. 7C is a perspective view showing a mobile object in which an electronic device is mounted.

A personal computer 500 shown in FIG. 7A has the electronic device 100 mounted therein as an example, and further has a keyboard 501, a main body 502 including the keyboard 501, and a display unit 503. The display unit 503 is rotatably supported through a hinge structure with respect to the main body 502. In the personal computer 500 having the above configuration, the electronic device 100 is embedded as a timing device, and withstand vibration, impact, or the like when the personal computer 500 is carried, thereby contributing to performance maintenance of the personal computer 500.

A mobile phone 600 shown in FIG. 7B has the electronic device 100 mounted therein as an example, and further has a plurality of operating buttons 601, an ear piece 602, and a mouth piece 603, and an antenna (not shown). A display unit 604 is arranged between the operating buttons 601 and the ear piece 602. In the mobile phone 600 having the above configuration, the electronic device 100 is embedded as a timing device, and withstands vibration, impact, or the like when the mobile phone 600 is carried, thereby contributing to performance maintenance of the mobile phone 600.

A mobile object 700 shown in FIG. 7C corresponds to, for example, a vehicle or the like. In this case, in the mobile object 700 which is an automobile, an electronic device 400 which includes the crystal vibrating piece 40 as an electronic component and is configured to detect acceleration, inclination, or the like is mounted. In the mobile object 700, the electronic device 400 is embedded in an electronic control unit (ECU) 703 which is mounted in a vehicle body 701. The electronic control unit 703 recognizes the movement state, posture, or the like by detecting the acceleration, inclination, or the like of the vehicle body 701 using the electronic device 400, thereby accurately performing control of the tire 702 or the like. Therefore, the mobile object 700 can perform stable traveling safely.

The electronic device 100, 200, or 300, or the electronic device 400 may be mounted in, for example, a digital still camera, an ink jet ejection apparatus, a television, a video camera, a video recorder, a car navigation system, an electronic organizer, an electronic dictionary, an electronic calculator, an electronic game machine, a work station, a security television monitor, electronic binoculars, a POS terminal, a medical instrument (for example, an electronic thermometer, a sphygmomanometer, a blood glucose meter, an electrocardiographic measurement apparatus, an ultrasonic diagnosis apparatus, or an electronic endoscope), a fish finder, various measurement instruments/meters (for example, meters of a vehicle, an aircraft, and a vessel), a flight simulator, or the like according to the function, in addition to the personal computer 500, the mobile phone 600, and the mobile object 700 described above.

The entire disclosure of Japanese Patent Application No. 2012-175752, filed Aug. 8, 2012 is expressly incorporated by reference herein.

What is claimed is:

1. A method of manufacturing an electronic device, the method comprising:
preparing a lid having a seal hole, a package having a metalization portion and constituting an internal space along with the lid, and an electronic component;
mounting the electronic component in the package;
placing the lid on the package such that the seal hole and the metalization portion overlap each other in plan view;
welding the outer circumferential portion of the lid and the package; and
irradiating an energy beam to bond the seal hole and the metalization portion and sealing the internal space.

2. The method according to claim 1,
wherein a metal solder is arranged on one surface of the lid, and
in the bonding of the seal hole and the metalization portion, the one surface is arranged on a surface side of the lid placed on the metalization portion, and the seal hole and the metalization portion are bonded together by the metal solder.

3. The method according to claim 2,
wherein the metal solder is a silver solder or a gold (Au)/tin (Sn) alloy solder.

4. The method according to claim 1,
wherein, in the bonding of the seal hole and the metalization portion, a fillet-like portion is formed between the inner surface of the seal hole and the metalization portion.

5. The method according to claim 1,
wherein the metalization portion of the package to be prepared in the preparing of the lid, the package, and the electronic component has a width in plan view at a position where the seal hole is arranged greater than a width in plan view at a different position.

6. The method according to claim 1,
wherein the seal hole is formed by punching by press, and
in the placing of the lid, a surface of the lid on which punching starts is placed on the package.

7. An electronic device comprising:
a lid having a hole portion;
a package; and
an electronic component which is in an internal space formed by bonding the lid and the package,
wherein the hole portion is arranged at a position overlapping a bonded portion of the lid and the package in plan view.

8. An electronic apparatus in which the electronic device according to claim 7 is mounted.

9. A mobile object in which the electronic device according to claim 7 is mounted.
